(19) United States
(12) Patent Application Publication
(10) Pub. No.: US 2025/0372923 A1
(43) Pub. Date: Dec. 4, 2025

(54) STAGE PIN RELEASE LEVER

(71) Applicant: Innovative Dimmers, LLC, Van Nuys, CA (US)

(72) Inventors: Robert Salazar, JR., San Gabriel, CA (US); Thomas J. Sievers, Newbury Park, CA (US)

(21) Appl. No.: 19/187,421

(22) Filed: Apr. 23, 2025

Related U.S. Application Data
(60) Provisional application No. 63/653,433, filed on May 30, 2024.

(51) Int. Cl. H01R 13/633; H01R 13/04; H01R 13/629; H01R 13/73; H05K 5/02

(52) U.S. Cl. CPC H01R 13/6335; H01R 13/04; H01R 13/62938; H01R 13/73; H05K 5/0247

(57) ABSTRACT

A stage pin release system includes an electronics box and a release lever. The electronics box includes a first stage pin electrical connection member that has one or more first electrical contacts. The release lever has a release lever body that includes a release lever handle and a release lever separating base. When a second stage pin electrical connection member is electrically connected to the first stage pin electrical connection member at the electronics box: (i) the release lever separating base is configured to be positioned between the electrically connected first and second stage pin electrical connection members, and (ii) upon application of a removal force at the release lever handle, the release lever separating base is configured to disconnect the electrical connection between the first and second stage pin electrical connection members.

### RELATED APPLICATION

This application claims the benefit of U.S. Provisional Application No. 63/653,433, filed May 30, 2024, the entire contents of which are incorporated herein by reference.

### TECHNICAL FIELD

This disclosure relates generally to device, system, and method embodiments of stage pin release levers. Embodiments disclosed herein can be configured to position a stage pin release lever relative to electrically connected stage pin electrical connection members at an electronics box and to disconnect the electrically connected stage pin electrical connection members using the stage pin release lever.

### BACKGROUND

Stage pin connectors, sometimes referred to as “Bates Connectors,” are used in the entertainment lighting industry to electrically connect a one or more light sources to a control interface that is remote from the one or more light sources. This electrical connection can allow a user to input lighting controls at the control interface to control the remotely located one or more light sources. However, because a significant friction force can be present between the electrically connected stage pin connectors, manually disconnecting the electrically connected stage pin connectors can be time-consuming, ergonomically adverse, and labor intensive.

### SUMMARY

This disclosure in general describes device, system, and method embodiments relating to a stage pin release lever. For example, a stage pin release lever can be configured to be positioned between electrically connected first and second stage pin electrical connection members and, when the release lever is so positioned and a removal force is applied at the release lever, the release lever can be configured to disconnect the electrical connection between the first and second stage pin electrical connection members. Because a significant friction force can be present between electrically connected stage pin connectors, manually disconnecting the electrically connected stage pin connectors via a user's hands can be time-consuming, ergonomically adverse, and labor intensive. This is particularly problematic in the entertainment lighting industry where lighting sources and controls are portable and moved frequently, thus increasing the burden associated with the likewise frequent and necessary electrical disconnection of stage pin connectors.

As such, the release lever can be useful in providing a mechanism for more efficient, easier, and quicker electrical and mechanical disconnection of stage pin electrical connection members. This can also help to reduce or eliminate the need to manually apply force (e.g., via a user's hand(s)) at one or both of the connected first and second stage pin electrical connection members. Moreover, the configuration of the release lever can help to transfer force applied at the release lever (e.g., at a handle at the release lever) into a contact force that is applied at the mechanical connection interface between the electrically and mechanically connected first and second stage pin electrical connection members. By transferring the force applied at the handle of the release lever into a contact force applied by the release lever at the mechanical connection interface between the electrically and mechanically connected first and second stage pin electrical connection members, the connected first and second stage pin electrical connection members can be more efficiently disconnected. And, at the same time, the release lever can allow for quicker electrical disconnection of stage pin connectors, which time savings can be particularly useful in the entertainment lighting industry.

One embodiment includes a stage pin release system. This system embodiment includes an electronics box and a release lever. The electronic box includes an electronics box housing that includes a first stage pin electrical connection member. The first stage pin electrical connection member includes one or more first electrical contacts at the electronics box housing. The release lever includes a release lever body. The release lever body includes a release lever handle and a release lever separating base. The release lever separating base is spaced apart along the release lever body from the release lever handle. When a second stage pin electrical connection member is electrically connected to the first stage pin electrical connection member at the electronics box housing: (i) the release lever separating base is configured to be positioned between the electrically connected first and second stage pin electrical connection members, and (ii) upon application of a removal force at the release lever handle, the release lever separating base is configured to disconnect the electrical connection between the first and second stage pin electrical connection members.

In a further embodiment of this system, the first stage pin electrical connection member includes a recessed slot at the electronics box housing. For example, the one or more first electrical contacts comprise two or more male prongs at the recessed slot at the electronics box housing. The second stage pin electrical connection member can include one or more second electrical contacts that include two or more female prong receptacles. According to this example, when the second stage pin electrical connection member is electrically connected to the first stage pin electrical connection member at the electronics box housing: (i) the two or more male prongs can be configured to be received within the two or more female prong receptacles at the recessed slot, and (ii) the release lever separating base can be configured to be positioned between a distal end portion of the second stage pin electrical connection member and a base surface of the recessed slot.

In a further embodiment of this system, the release lever further comprises: a release lever rotational shaft that is configured to rotatably attach the release lever body to the electronics box housing. The release lever rotational shaft can be spaced apart about the release lever body from each of the release lever handle and the release lever separating base. For example, the release lever rotational shaft can extend along a release lever rotational shaft longitudinal axis, and the release lever handle can extend along a release lever handle longitudinal axis, with the release lever rotational shaft longitudinal axis being parallel to the release lever handle longitudinal axis.

As noted, in some applications, the first stage pin electrical connection member can include a recessed slot at the electronics box housing. For some embodiments configured for such an application, the release lever rotational shaft can be configured to be positioned within the recessed slot at the electronics box housing while the release lever handle is positioned outside of the recessed slot at the electronics box housing. The release lever rotational shaft can include: a first rotatable attachment member at a first longitudinal end portion of the release lever rotational shaft configured to rotationally attach to a first side of the recessed slot, and a second rotatable attachment member at a second, opposite longitudinal end portion of the release lever rotational shaft configured to rotationally attach to a second, opposite side of the recessed slot. The removal force can be a rotational force applied at the release lever handle. Upon application of the rotational force, the release lever rotational shaft can be configured to rotate relative to recessed slot to cause the release lever separating base to move relative to the recessed slot to thereby disconnect the electrical connection between the first and second stage pin electrical connection members. For instance, the release lever separating base can be configured to disconnect the electrical connection between the first and second stage pin electrical connection members by moving the second stage pin electrical connection member away from the first stage pin electrical connection member and recessed slot upon application of the rotational force at the release lever handle.

In additional or alternative examples of this embodiment, the release lever separating base can include: a first release lever separating base portion at a first side of the release lever body, and a second release lever separating base portion at a second, opposite side of the release lever body and spaced apart from the first release lever separating base portion to define a prong receiving gap between the first release lever separating base portion and the second release lever separating base portion. The release lever rotational shaft can be offset from each of the first release lever separating base portion and the second release lever separating base portion.

In a further embodiment of this system, the release lever separating base can define a thickness that is equal to or less than 3.175 mm. Additionally or alternatively, the release lever separating base can define a flexural modulus that is greater than a flexural modulus of the release lever handle.

Another embodiment includes a method. This method embodiment includes a step of electrically connecting a second stage pin electrical connection member to a first stage pin electrical connection member that is at an electronics box. The electronics box includes an electronics box housing that includes a first stage pin electrical connection member. The first stage pin electrical connection member includes one or more first electrical contacts at the electronics box housing. The electronics box includes a release lever at the first stage pin electrical connection member such that the second stage pin electrical connection member is electrically connected to the first stage pin electrical connection member at the electronics box with a release lever separating base of the release lever positioned between the electrically connected first and second stage pin electrical connection members. This method embodiment also includes a step of disconnecting the electrical connection between the first and second stage pin electrical connection members by applying a removal force at a handle of the release lever to cause the release lever separating base of the release lever to move the second stage pin electrical connection member away from the first stage pin electrical connection member to disconnect the electrical connection.

In a further embodiment of this method, the first stage pin electrical connection member includes a recessed slot at the electronics box housing, and the removal force is applied at the handle of the release lever at a location outside of the recessed slot. As one example, when the removal force is applied at the handle of the release lever at a location outside of the recessed slot, the release lever separating base of the release lever can be caused to move the second stage pin electrical connection member away from the first stage pin electrical connection member within the recessed slot to disconnect the electrical connection between the first and second stage pin electrical connection members. For instance, the removal force can be a rotational force applied at the handle of the release lever at the location outside of the recessed slot. In some such embodiments, the release lever can further include: a release lever rotational shaft that rotatably attaches the release lever within the recessed slot, and the release lever rotational shaft can be spaced apart from each of the handle of the release lever and the release lever separating base. For instance, applying the rotational force at the handle of the release lever can cause the release lever rotational shaft to rotate relative to recessed slot to cause the release lever separating base to move relative to the recessed slot to thereby move the second stage pin electrical connection member away from the first stage pin electrical connection member within the recessed slot to disconnect the electrical connection between the first and second stage pin electrical connection members.

In a further embodiment of this method, the release lever separating base can include: a first release lever separating base portion at a first side of the release lever body, and a second release lever separating base portion at a second, opposite side of the release lever body and spaced apart from the first release lever separating base portion to define a prong receiving gap between the first release lever separating base portion and the second release lever separating base portion. In such an embodiment, electrically connecting the second stage pin electrical connection member to the first stage pin electrical connection member can include receiving the one or more first electrical contacts of the first stage pin electrical connection member at the prong receiving gap when the first release lever separating base portion and the second release lever separating base portion are positioned between the electrically connected first and second stage pin electrical connection members. In one particular such example, applying the removal force at the handle of the release lever can cause each of the first release lever separating base portion and the second release lever separating base portion to move the second stage pin electrical connection member away from the first stage pin electrical connection member to disconnect the electrical connection between the first and second stage pin electrical connection members.

The details of one or more examples are set forth in the accompanying drawings and the description below. Other features, objects, and advantages will be apparent from the description and drawings, and from the claims.

### BRIEF DESCRIPTION OF DRAWINGS

The following drawings are illustrative of particular examples of the present invention and therefore do not limit the scope of the invention. The drawings are intended for use in conjunction with the explanations in the following detailed description wherein like reference characters denote like elements. Examples of the present invention will hereinafter be described in conjunction with the appended drawings.

FIG. 1 is a perspective view of an electronics box. More specifically, FIG. 1 is a perspective view of a first stage pin electrical connection member at an electronics box disconnected from a second stage pin electrical connection member.

FIG. 2 is a top plan view of a release lever positioned at the first stage pin electrical connection member of the electronics box, with the second stage pin electrical connection member disconnected from the first stage pin electrical connection member at the electronics box.

FIGS. 3A-3C illustrate the release lever positioned relative to the first and second stage pin electrical connection members when the first and second stage pin electrical connection members are electrically connected at the electronics box. FIG. 3A is a perspective view, FIG. 3B is a first side elevational view, and FIG. 3C is a second side elevational view, which is rotated ninety degrees from the first side elevational view at FIG. 3B, each showing the release lever positioned relative to the electrically connected first and second stage pin electrical connection members.

FIG. 4 is the side elevational view of FIG. 3B but with the release lever being used to move the second stage pin electrical connection member away from the first stage pin electrical connection member at the electronics box.

FIG. 5 is the side elevational view of FIG. 3B but with the release lever having been used to disconnect the electrical connection between the first and second stage pin electrical connection members.

FIG. 6 is a flow diagram of an embodiment of a method for disconnecting an electrical connection between first and second stage pin electrical connection members using a release lever.

### DETAILED DESCRIPTION

The following detailed description is exemplary in nature. The following description provides some practical illustrations for implementing examples of the present invention. Those skilled in the art will recognize that many of the noted examples have a variety of suitable alternatives.

This disclosure describes examples of embodiments relating to a stage pin release lever that can be configured to be positioned between electrically connected first and second stage pin electrical connection members and, when the release lever is so positioned and a removal force is applied at the release lever the release lever can be configured to disconnect the electrical connection between the first and second stage pin electrical connection members. As such, the release lever can be useful in providing a mechanism for more efficient, easier, and quicker electrical and mechanical disconnection of stage pin electrical connection members.

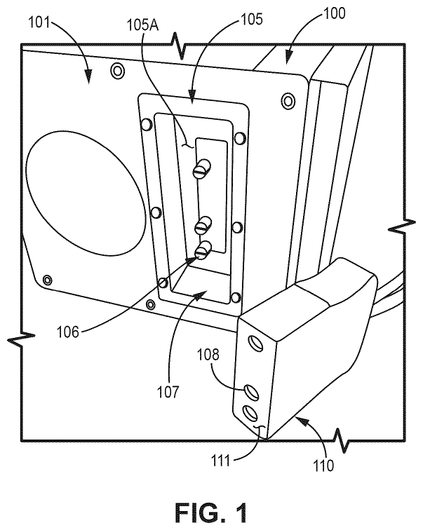

FIG. 1 is a perspective view of an electronics box 100. As one example, the electronics box 100 can be a dimmer electronics box that can be used in the entertainment industry, for instance, to provide an electrical connection junction box for various electrical connections. The electronics box 100 can include one or more control inputs thereat, for instance, control inputs to actuate a lighting change, such as to actuate a light dimming or brightening, on a set of an entertainment production. In addition to the one or more control inputs, such as for lighting controls, the electronics box 100 can include one or more plugs at which one or more electrical connections can be made, for instance, one or more electrical connections to one or more light sources on the set of an entertainment production. One example of such an electronics box 100 can be the RatPac® Lunchbox Dimmer (e.g., Edison Dimmer or Socapex Dimmer). Though other embodiments within the scope of this disclosure can include a variety of other types of electronics boxes (e.g., a variety of types of lunchbox dimmers), such as any of a variety of electronics boxes where an electrical connection is made between members at a recessed slot of the electronics box.

The electronics box 100 can include an electronics box housing 101. The electronics box housing 101 can include thereat a first stage pin electrical connection member 105. The first stage pin electrical connection member 105 can be configured to mechanically connect to a second stage pin electrical connection member 110 to create an electrical connection between the first and second stage pin electrical connection members 105, 110 at the electronics box housing 101. For example, the second stage pin electrical connection member 110 can electrically couple to the first stage pin electrical connection member 105 at one end and to a power source (e.g., AC line power at a wall outlet) at another opposite end such that the second stage pin electrical connection member 110 can provide input power to the electronics box 100 when the first and second stage pin electrical connection members 105, 110 are electrically connected at the electronics box housing 101.

As shown for the illustrated example, the first stage pin electrical connection member 105 can include a recessed slot 107 at the electronics box housing 101. In addition, the first stage pin electrical connection member 105 can include one or more first electrical contacts 106 at the electronics box housing 101. The one or more first electrical contacts 106 can be at the recessed slot 107 at the electronics box housing 101. As one example shown at FIG. 1, the first stage pin electrical connection member 105 can include the one or more first electrical contacts 106 as two or more male prongs at the recessed slot 107 at the electronics box housing 101. The second stage pin electrical connection member 110 can include one or more second electrical contacts 108. For examples, such as that shown here, where the first stage pin electrical connection member 105 includes two or more male prongs at the recessed slot 107 as the first electrical contacts 106 at the first stage pin electrical connection member 105, the second stage pin electrical connection member 110 can include two or more complementary female prong receptacles as the second electrical contacts 108. FIG. 1 shows the first stage pin electrical connection member 105 at an electronics box 101 disconnected from the second stage pin electrical connection member 110, and the first and second stage pin electrical connection members 105, 110 can be electrically connected by mechanically connecting the second electrical contacts 108 to the first electrical contacts 106 at the recessed slot 107 (e.g., by placing the male prongs at the recessed slot 107 into the female prong receptacles of the second electrical contacts 108).

When the first and second stage pin electrical connection members 105, 110 are mechanically, and thus electrically, connected, a significant friction force can be present between the connected components. However, because the first and second stage pin electrical connection members 105, 110 can have a mechanical connection interface therebetween at the location of the recessed slot 107, disconnecting the first and second stage pin electrical connection members 105, 110 can be manually difficult to do simply by pulling or applying other force at the second stage pin electrical connection member 110 to try and disconnect it from the first stage pin electrical connection member 105 since application of this pulling at the second stage pin electrical connection member 110 can be spaced apart from the mechanical connection interface between the first and second stage pin electrical connection members 105, 110 at the recessed slot 107. To reduce the time and effort needed to disconnect the first and second stage pin electrical connection members 105, 110 at the recessed slot 107, a disconnection force can be applied closer to (e.g., at) this mechanical connection interface between the connected first and second stage pin electrical connection members 105, 110 within the recessed slot 107 at the housing 101. Given the relatively small clearance available around the connected first and second stage pin electrical connection members 105, 110 and the significant frictional retention force between the connected first and second stage pin electrical connection members 105, 110, simply placing a user's hands at the mechanical connection interface between the connected first and second stage pin electrical connection members 105, 110 within the recessed slot 107 can be impeded and/or impractical.

As will be described further below, a stage pin release lever can be configured to be positioned at or near the mechanical connection interface between the electrically connected first and second stage pin electrical connection members 105, 110. When the release lever is so positioned and a removal force is applied at the release lever (e.g., at a handle of the release lever), the release lever can be configured to disconnect the electrical connection between the first and second stage pin electrical connection members (e.g., by applying a force at the mechanical connection interface between the first and second stage pin electrical connection members). As such, the release lever can be useful in providing a mechanism for more efficient, easier, and quicker electrical and mechanical disconnection of stage pin electrical connection members.

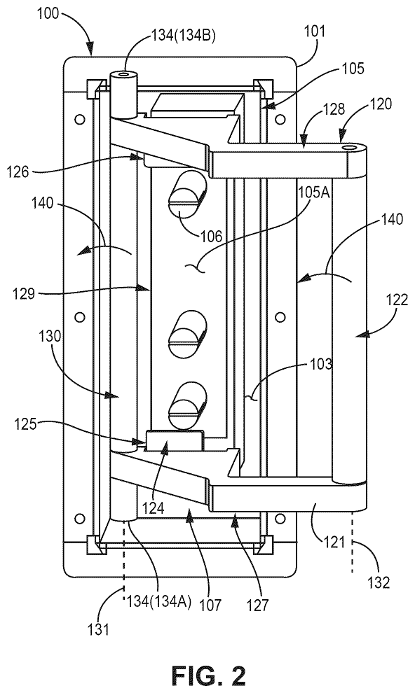

FIG. 2 is a top plan view of a stage pin release lever 120 positioned at the first stage pin electrical connection member 105 of the electronics box 100. For FIG. 2, the second stage pin electrical connection member 110 is disconnected from the first stage pin electrical connection member 105 and thus not shown. For example, the release lever 120 can be positioned at the first stage pin electrical connection member 105, such as positioned at least partially within the recessed slot 107, prior to electrically connecting the second stage pin electrical connection member 110 to the first stage pin electrical connection member 105 at the recessed slot 107. In one specific such example, the electronics box 100 can include the release lever 120 as an associated (e.g., integrated) component, but in another specific such example the release lever 120 can be a separate, independent component from the electronics box 100 and positioned at least partially at the recessed slot 107.

The release lever 120 can include a release lever body 121. The release lever body 121 can include a release lever handle 122 and a release lever separating base 124. The release lever handle 122 can be configured to be gripped by a hand of a user to apply at the release lever handle 122 a removal force to cause the first and second stage pin electrical connection members to disconnect, as will be described further. The release lever separating base 124 can be spaced apart, along the release lever body 121, from the release lever handle 122. As seen at the example of FIG. 2, the release lever 120 can be configured such that the release lever separating base 124 is configured to be positioned within the recessed slot 107 while the release lever handle 122 is positioned outside of the recessed slot 107.

The release lever separating base 124 at the release lever 120 can include one or more release lever separating base portions. The illustrated embodiment of the release lever separating base 124 includes a first release lever separating base portion 125 and a second release lever separating base portion 126. The first release lever separating base portion 125 can be at a first side 127 of the release lever body 121, and the second release lever separating base portion 126 can be at a second, opposite side 128 of the release lever body 121. The second release lever separating base portion 126 can be spaced apart from the first release lever separating base portion 125 to define a prong receiving gap 129 between the first release lever separating base portion 125 and the second release lever separating base portion 126. As shown at the example of FIG. 2, the release lever 120 can be placed at the recessed slot 107 such that the first release lever separating base portion 125 is at one side of the first electrical contacts (e.g., male prongs) 106 and the second release lever separating base portion 126 is at another, opposite side of the first electrical contacts (e.g., male prongs) 106, with the first electrical contacts (e.g., male prongs) 106 at the prong receiving gap 129. In one particular such example, the release lever 120 can be placed at the recessed slot 107 such that the first release lever separating base portion 125 contacts a surface, such as proximal surface 105A, at the first stage pin electrical connection member 105 at one side of the first electrical contacts (e.g., male prongs) 106 and the second release lever separating base portion 126 contacts the same proximal surface 105A at the first stage pin electrical connection member 105 at another, opposite side of the first electrical contacts (e.g., male prongs) 106, with the first electrical contacts (e.g., male prongs) 106 extending through and protruding out from prong receiving gap 129.

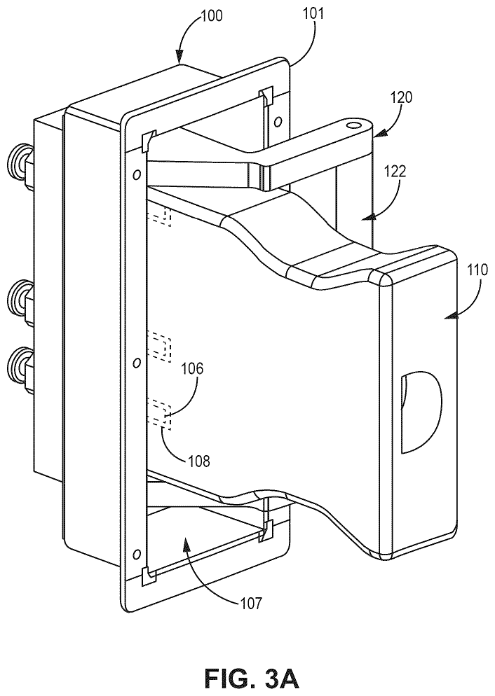

Thus, the release lever separating base 124 can be configured to sit between the electrically connected first and second stage pin electrical connection members 105, 110 at the recessed slot 107 and, upon application of a removal force at the release lever 120 (e.g., at the handle 122), the release lever separating base 124 can be configured to impart movement between the electrically connected first and second stage pin electrical connection members 105, 110 to thereby act to disconnect the first and second stage pin electrical connection members 105, 110. In some embodiments, the release lever separating base 124 can include one or more features useful for accomplishing such functions. For instance, to help sit the release lever separating base 124 between the electrically connected first and second stage pin electrical connection members 105, 110, the release lever separating base 124 (e.g., each of the first release lever separating base portion 125 and the second release lever separating base portion 126) can have a thickness 123 (see, e.g., FIG. 3B) that is equal to or less than 3.175 mm, such as equal to or less than 1.5875 mm. In some additional or alternative embodiments, to help the release lever separating base 124 be configured to impart movement between the electrically connected first and second stage pin electrical connection members 105, 110, the release lever separating base 124 can have an increased rigidity relative to one or more other portions of the body 121. For example, the release lever separating base 124 can include a first type of rigid material (e.g., carbon fiber, aluminum, etc.) that is different than a material type at another, different portion of the body 121. As one particular, non-limiting example, the release lever separating base 124 can define a flexural modulus that is greater than a flexural modulus of another, different portion of the body 121. For instance, the release lever separating base 124 can define a flexural modulus that is greater than a flexural modulus of handle 122.

The illustrated embodiment of the release lever 120 further includes a release lever rotational shaft 130. The release lever rotational shaft 130 can be configured to rotatably attach the release lever body 121 to the electronics box housing 101. For example, the release lever rotational shaft 130 can be configured to rotatably attach the release lever body 121 to the electronics box housing 101 within the recessed slot 107. This can include the release lever rotational shaft 130 being configured to be positioned within the recessed slot 107 at the electronics box housing 101 while the release lever handle 122 is positioned outside of the recessed slot 107 at the electronics box housing 101. This can allow a user to grasp the handle 122 while the release lever separating base 124 and the release lever rotational shaft 130 are within the recessed slot 107.

The release lever rotational shaft 130 can be spaced apart about the release lever body 121 from each of the release lever handle 122 and the release lever separating base 124. The release lever rotational shaft 130 can extend along a release lever rotational shaft longitudinal axis 131, the release lever handle 122 can extend along a release lever handle longitudinal axis 132, and the release lever rotational shaft longitudinal axis 131 can be parallel to the release lever handle longitudinal axis 132.

To rotatably attach the release lever body 121 to the electronics box housing 101, the release lever rotational shaft 130 can include one or more rotatable attachment members 134. The one or more rotatable attachment members 134 can, for instance, be configured to rotatably attach the release lever rotational shaft 130 at the recessed slot 107 of the electronics box housing 101 such that the release lever rotational shaft 130 can be configured to rotate relative to the electronics box housing 101 and thus rotate relative to the recessed slot 107. For example, upon application of a removal force at the handle 122 in a direction 140, the release lever rotational shaft 130 can be caused to rotate (e.g., caused to rotate about the release lever rotational shaft longitudinal axis 131 also in the direction 140) relative to the housing 101 and recessed slot 107 which can correspondingly act to move the release lever separating base 124 relative to the electronics box housing 101 and recessed slot 107. As shown here, the release lever rotational shaft 130 can be offset from each of the first release lever separating base portion 125 and the second release lever separating base portion 126, for instance such that the release lever rotational shaft longitudinal axis 131 is offset from and does not intersect the first and second release lever separating base portions 125, 126. Such movement of the release lever separating base 124 can act to apply a disconnection force at the first and/or second electrical connection members 105, 110 (e.g., at the second electrical connection member 110) to help electrically disconnect the first and second electrical connection members 105, 110.

The illustrated embodiment shows that at least two rotatable attachment members 134 can be used to rotatably attach the release lever rotational shaft 130 to the housing 101 (e.g., at the recessed slot 107). In particular, the illustrated embodiment at FIG. 2 shows the release lever rotational shaft 130 having a first rotatable attachment member 134A and a second rotatable attachment member 134B. The first rotatable attachment member 134A is at one side of the release lever rotational shaft 130 and the second rotatable attachment member 134B is at another, opposite side of the release lever rotational shaft 130. The first rotatable attachment member 134A can be at a first longitudinal end portion of the release lever rotational shaft 130 at first side 127 of body 121 and configured to rotationally attach to a first side of the recessed slot 107, while the second rotatable attachment member 134B can be at a second, opposite longitudinal end portion of the release lever rotational shaft 130 at second side 128 of body 121 and configured to rotationally attach to a second, opposite side of the recessed slot 107. The first rotatable attachment member 134A can be configured to rotatably connect the release lever rotational shaft 130 to the recessed slot 107 at a same side of the first electrical contacts (e.g., male prongs) 106 where the first release lever separating base portion 125 is positioned, and the second rotatable attachment member 134B can be configured to rotatably connect the release lever rotational shaft 130 to the recessed slot 107 at a same side of the first electrical contacts (e.g., male prongs) 106 where the second release lever separating base portion 126 is positioned.

For some embodiments, the release lever 120 can be a single, integral part. As such, the handle 122, the release lever separating base 124, and the release lever rotational shaft 130 can be integral portions of a single part release lever body 121. For example, such an integral release lever body 121 can be manufactured via injection molding, additive manufacturing (e.g., three-dimensional printing), or subtractive manufacturing (e.g., machining, etching, etc.). In other embodiments, the release lever body 121 can be made of multiple, coupled parts. For example, a multi-part release body 121 can be manufacturing using fastened together parts, for instance a release lever rotational shaft part fastened to a release lever body having the handle and release lever separating base.

FIGS. 3A-3C illustrate the release lever 120 positioned relative to the first and second stage pin electrical connection members 105, 110 when the first and second stage pin electrical connection members 105, 110 are electrically connected at the electronics box 100. FIG. 3A is a perspective view, FIG. 3B is a first side elevational view, and FIG. 3C is a second side elevational view, which is rotated ninety degrees from the first side elevational view at FIG. 3B, each showing the release lever 120 positioned relative to the electrically connected first and second stage pin electrical connection members 105, 110. When the second stage pin electrical connection member 110 is electrically connected to the first stage pin electrical connection member 105 at the electronics box housing 101, the release lever separating base 124 can be configured to be positioned between the electrically connected first and second stage pin electrical connection members 105, 110.

For example, as seen at the example at FIGS. 3A-3C, when the second stage pin electrical connection member 110 is electrically connected to the first stage pin electrical connection member 105 at the electronics box housing 101: (i) the two or more male prongs 106, at the first stage pin electrical connection member 105, can be configured to be received within the two or more female prong receptacles 108, at the second stage pin electrical connection member 110, at the recessed slot 107, and (ii) the release lever separating base 124 can be configured to be positioned between a distal end portion 111 of the second stage pin electrical connection member 110 and a base surface 103 of the recessed slot 107 (e.g., the release lever separating base 124 can be configured to be positioned between a distal end portion 111 of the second stage pin electrical connection member 110 and a proximal surface 105A at the first stage pin electrical connection member 105). For embodiments that include multiple portions of the release lever separating base 124—e.g., the first release lever separating base portion 125 and second release lever separating base portion 126—when the second stage pin electrical connection member 110 is electrically connected to the first stage pin electrical connection member 105 at the electronics box housing 101: (i) the two or more male prongs 106, at the first stage pin electrical connection member 105, can be configured to be received within the two or more female prong receptacles 108, at the second stage pin electrical connection member 110, at the recessed slot 107, and (ii) each of the first release lever separating base portion 125 and the second release lever separating base portion 126 can be configured to be positioned between a distal end portion 111 of the second stage pin electrical connection member 110 and the base surface 103 of the recessed slot 107 (e.g., each of the first release lever separating base portion 125 and the second release lever separating base portion 126 can be configured to be positioned between a distal end portion 111 of the second stage pin electrical connection member 110 and the proximal surface 105A at the first stage pin electrical connection member 105).

Upon application of a removal force at the release lever 120 (e.g., at the release lever handle 122), the release lever separating base 124 can be configured to disconnect the electrical connection between the first and second stage pin electrical connection members 105, 110.

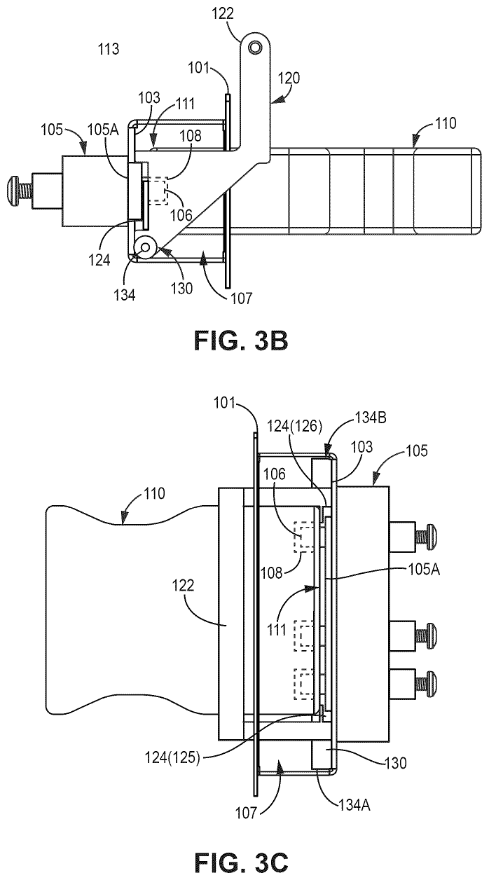

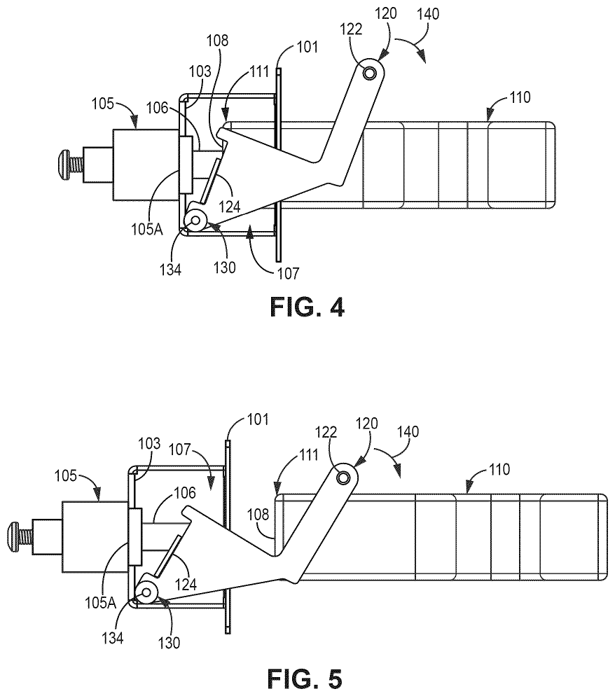

Examples of this will be discussed as follows in reference to the exemplary sequence shown at FIGS. 4 and 5 for using the release lever separating base 124 to disconnect the first and second stage pin electrical connection members 105, 110. FIG. 4 is the side elevational view of FIG. 3B but with the release lever 120 being used to move the second stage pin electrical connection member 110 away from the first stage pin electrical connection member 105 at the electronics box 100 to disconnect the second stage pin electrical connection 110 from the first stage pin electrical connection member 105. And FIG. 5 is also the side elevational view of FIG. 3B but with the release lever having been used to disconnect the electrical connection between the first and second stage pin electrical connection members. As such, FIG. 4 can represent a first phase of a sequence for electrically disconnecting the first and second stage pin electrical connection members 105, 110 using the release lever 120, and FIG. 5 can represent a second, subsequent phase of a sequence for electrically disconnecting the first and second stage pin electrical connection members 105, 110 using the release lever 120.

For instance, first the release lever 120 can be at the electronics box 100, such as shown at FIGS. 3A-3C. Then the removal force can be applied at the handle 122 to initially begin to move the second stage pin electrical connection member 110 away from the first stage pin electrical connection member 105 via contact between the release lever separating base 124 and the second stage pin electrical connection member 110, such as shown at FIG. 4. Then as the removal force is continued to be applied (e.g., the removal force is continued to be applied in the direction 140) the second stage pin electrical connection member 110 can become fully separate and mechanically and electrically disconnected from the first stage pin electrical connection member 105 via the contact between the release lever separating base 124 and the second stage pin electrical connection member 110, such as shown at FIG. 5.

Referring to the examples shown at FIGS. 4 and 5, when the second stage pin electrical connection member 110 is electrically connected to the first stage pin electrical connection member 105 at the recessed slot 107 and the release lever separating base 124 is positioned between the electrically connected first and second stage pin electrical connection members 105, 110, upon application of the removal force (e.g., applied via a user's hand gripped at the handle 122), such as in the direction 140 at the release lever handle 122, the release lever separating base 124 can be configured to disconnect the electrical connection between the first and second stage pin electrical connection members 105, 110 by imparting relative movement between the electrically connected first and second stage pin electrical connection members 105, 110 as a result of release lever separating base 124 contact at the mechanical connection interface between the first and second stage pin electrical connection members 105, 110. The release lever separating base 124 can be configured to so disconnect the electrical connection between the first and second stage pin electrical connection members 105, 110 by contacting the second stage pin electrical connection member 110 at the distal end portion 111, as a result of the application of the removal force at the handle 122, to thereby cause the second stage pin electrical connection member 110 to move away from the first stage pin electrical connection member 105. More specifically, the examples at FIGS. 4 and 5 show that the release lever separating base 124 can be configured to disconnect the electrical connection between the first and second stage pin electrical connection members 105, 110 via the release lever separation base 124 contacting the distal end portion 111 of the second stage pin electrical connection member 110, as a result of the application of the removal force at the handle 122, to thereby cause the second stage pin electrical connection member 110 to move away from the proximal surface 105A at the first stage pin electrical connection member 105.

For embodiments of the release lever 120 that include the release lever rotational shaft 130, application of the removal force at the release lever 120 can cause the release lever rotational shaft 130 to rotate relative to the housing 101 (e.g., and relative to the first stage pin electrical connection member 105) to thereby cause the release lever separation base 124 to move toward the distal end portion 111 of the second stage pin electrical connection member 110. As one example, the removal force can be a rotational force applied at the release lever handle 122, such as a rotational force applied at the handle 122 in the direction 140. For instance, when the removal force is applied at the handle 122 in the direction 140, the release lever rotational shaft 130 can be configured to rotate, such as about the release lever rotational shaft longitudinal axis 131, relative to recessed slot 107 also in the direction 140 to cause the release lever separating base 124 to also move in the direction 140 to thereby be brought into contact with, and move, the second stage pin electrical connection member 110 in a direction away from the recessed slot and away from the first stage pin electrical connection member 105, such as shown at FIGS. 4 and 5.

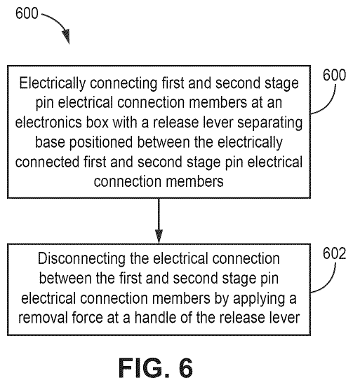

FIG. 6 is a flow diagram of an embodiment of a method 600 for disconnecting an electrical connection between first and second stage pin electrical connection members using a release lever. In some examples, the method 600 can be executed using one or more of the features disclosed elsewhere herein. As one such example, the method 600 can be executed using one or more (e.g., each) of the features related to the release lever 120 as disclosed elsewhere herein.

At step 601, the method 600 includes electrically connecting a second stage pin electrical connection member to a first stage pin electrical connection member that is at an electronics box. For example, the electronics box can include an electronics box housing that has the first stage pin electrical connection member. The first stage pin electrical connection member can have one or more first electrical contacts at the electronics box housing. The electronics box can have a release lever, such as release lever 120, at the first stage pin electrical connection member such that the second stage pin electrical connection member is electrically connected to the first stage pin electrical connection member at the electronics box with a release lever separating base of the release lever positioned between the electrically connected first and second stage pin electrical connection members.

Where execution of the method 600 includes use of release lever 120, some embodiments of release lever 120 can include multiple portions of the release lever separating base. For example, one such embodiment of the release lever 120 can include a first release lever separating base portion at a first side of the release lever body and a second release lever separating base portion at a second, opposite side of the release lever body and spaced apart from the first release lever separating base portion to define a prong receiving gap between the first release lever separating base portion and the second release lever separating base portion. For such embodiment, electrically connecting the second stage pin electrical connection member to the first stage pin electrical connection member can include receiving the one or more first electrical contacts of the first stage pin electrical connection member at the prong receiving gap at the release lever when the first release lever separating base portion and the second release lever separating base portion are positioned between the electrically connected first and second stage pin electrical connection members.

At step 602, the method 600 includes disconnecting the electrical connection between the first and second stage pin electrical connection members by applying a removal force at a handle of the release lever, such as release lever 120, to cause the release lever separating base of the release lever to move the second stage pin electrical connection member away from the first stage pin electrical connection member to disconnect the electrical connection. For example, the first stage pin electrical connection member can include a recessed slot at the electronics box housing such that when the removal force is applied at the handle of the release lever at a location outside of this recessed slot, the release lever separating base of the release lever can be caused to move the second stage pin electrical connection member away from the first stage pin electrical connection member within this recessed slot to disconnect the electrical connection between the first and second stage pin electrical connection members.

In one such example, the removal force can be a rotational force applied at the handle of the release lever at the location outside of the recessed slot. And in one particular, exemplary such application, the release lever can include a release lever rotational shaft that rotatably attaches the release lever within the recessed slot. The release lever rotational shaft can be spaced apart from each of the handle of the release lever and the release lever separating base. In this exemplary application, applying the rotational force at the handle of the release lever can cause the release lever rotational shaft to rotate relative to recessed slot to cause the release lever separating base to move relative to the recessed slot to thereby move the second stage pin electrical connection member away from the first stage pin electrical connection member within the recessed slot to disconnect the electrical connection between the first and second stage pin electrical connection members.

Where execution of the method 600 includes use of release lever 120, as noted, some embodiments of release lever 120 can include multiple portions of the release lever separating base. For such embodiments, applying the removal force at the handle of the release lever 120 can cause each of the first release lever separating base portion 125 and the second release lever separating base portion 126 to move the second stage pin electrical connection member 110 away from the first stage pin electrical connection member 105 to disconnect the electrical connection between the first and second stage pin electrical connection members 105, 110.

Various examples have been described. These and other examples are within the scope of this disclosure and the following claims.

What is claimed is:

1. A stage pin release system comprising:
an electronics box comprising an electronics box housing, the electronics box housing including a first stage pin electrical connection member, the first stage pin electrical connection member including one or more first electrical contacts at the electronics box housing; and
a release lever comprising a release lever body, the release lever body including a release lever handle and a release lever separating base, the release lever separating base spaced apart along the release lever body from the release lever handle,
wherein when a second stage pin electrical connection member is electrically connected to the first stage pin electrical connection member at the electronics box housing: (i) the release lever separating base is configured to be positioned between the electrically connected first and second stage pin electrical connection members, and (ii) upon application of a removal force at the release lever handle, the release lever separating base is configured disconnect the electrical connection between the first and second stage pin electrical connection members.

2. The system of claim 1,
wherein the first stage pin electrical connection member comprises a recessed slot at the electronics box housing, and
wherein the one or more first electrical contacts comprise two or more male prongs at the recessed slot at the electronics box housing.

3. The system of claim 2,
wherein the second stage pin electrical connection member comprises one or more second electrical contacts that include two or more female prong receptacles, and
wherein when the second stage pin electrical connection member is electrically connected to the first stage pin electrical connection member at the electronics box housing: (i) the two or more male prongs are configured to be received within the two or more female prong receptacles at the recessed slot, and (ii) the release lever separating base is configured to be positioned between a distal end portion of the second stage pin electrical connection member and a base surface of the recessed slot.

4. The system of claim 1, wherein the release lever further comprises:
a release lever rotational shaft that is configured to rotatably attach the release lever body to the electronics box housing, the release lever rotational shaft being spaced apart about the release lever body from each of the release lever handle and the release lever separating base.

5. The system of claim 4, wherein the release lever rotational shaft extends along a release lever rotational shaft longitudinal axis, wherein the release lever handle extends along a release lever handle longitudinal axis, and wherein the release lever rotational shaft longitudinal axis is parallel to the release lever handle longitudinal axis.

6. The system of claim 4,
wherein the first stage pin electrical connection member comprises a recessed slot at the electronics box housing,
wherein the release lever rotational shaft is configured to be positioned within the recessed slot at the electronics box housing while the release lever handle is positioned outside of the recessed slot at the electronics box housing.

7. The system of claim 6, wherein the release lever rotational shaft comprises: a first rotatable attachment member at a first longitudinal end portion of the release lever rotational shaft configured to rotationally attach to a first side of the recessed slot, and a second rotatable attachment member at a second, opposite longitudinal end portion of the release lever rotational shaft configured to rotationally attach to a second, opposite side of the recessed slot.

8. The system of claim 6, wherein the removal force is a rotational force applied at the release lever handle, wherein upon application of the rotational force, the release lever rotational shaft is configured to rotate relative to recessed slot to cause the release lever separating base to move relative to the recessed slot to thereby disconnect the electrical connection between the first and second stage pin electrical connection members.

9. The system of claim 8, wherein the release lever separating base is configured to disconnect the electrical connection between the first and second stage pin electrical connection members by moving the second stage pin electrical connection member away from the first stage pin electrical connection member and recessed slot upon application of the rotational force as the rotational force at the release lever handle.

10. The system of claim 6,
wherein the release lever separating base comprises: a first release lever separating base portion at a first side of the release lever body, and a second release lever separating base portion at a second, opposite side of the release lever body and spaced apart from the first release lever separating base portion to define a prong receiving gap between the first release lever separating base portion and the second release lever separating base portion, and
wherein the release lever rotational shaft is offset from each of the first release lever separating base portion and the second release lever separating base portion.

11. The system of claim 1, wherein the release lever separating base defines a thickness that is equal to or less than 3.175 mm.

12. The system of claim 11, wherein the release lever separating base defines a flexural modulus that is greater than a flexural modulus of the release lever handle.

13. A method comprising the steps of:
electrically connecting a second stage pin electrical connection member to a first stage pin electrical connection member that is at an electronics box, the electronics box comprising an electronics box housing that comprises the first stage pin electrical connection member, the first stage pin electrical connection member comprising one or more first electrical contacts at the electronics box housing, the electronics box having a release lever at the first stage pin electrical connection member such that the second stage pin electrical connection member is electrically connected to the first stage pin electrical connection member at the electronics box with a release lever separating base of the release lever positioned between the electrically connected first and second stage pin electrical connection members; and
disconnecting the electrical connection between the first and second stage pin electrical connection members by applying a removal force at a handle of the release lever to cause the release lever separating base of the release lever to move the second stage pin electrical connection member away from the first stage pin electrical connection member to disconnect the electrical connection.

14. The method of claim 13,
wherein the first stage pin electrical connection member comprises a recessed slot at the electronics box housing, and
wherein the removal force is applied at the handle of the release lever at a location outside of the recessed slot.

15. The method of claim 14, wherein, when the removal force is applied at the handle of the release lever at a location outside of the recessed slot, the release lever separating base of the release lever is caused to move the second stage pin electrical connection member away from the first stage pin electrical connection member within the recessed slot to disconnect the electrical connection between the first and second stage pin electrical connection members.

16. The method of claim 15, wherein the removal force is a rotational force applied at the handle of the release lever at the location outside of the recessed slot.

17. The method of claim 16, wherein the release lever further comprises: a release lever rotational shaft that rotatably attaches the release lever within the recessed slot, the release lever rotational shaft being spaced apart from each of the handle of the release lever and the release lever separating base.

18. The method of claim 17, wherein applying the rotational force at the handle of the release lever causes the release lever rotational shaft to rotate relative to recessed slot to cause the release lever separating base to move relative to the recessed slot to thereby move the second stage pin electrical connection member away from the first stage pin electrical connection member within the recessed slot to disconnect the electrical connection between the first and second stage pin electrical connection members.

19. The method of claim 13,
wherein the release lever separating base comprises: a first release lever separating base portion at a first side of the release lever body, and a second release lever separating base portion at a second, opposite side of the release lever body and spaced apart from the first release lever separating base portion to define a prong receiving gap between the first release lever separating base portion and the second release lever separating base portion, and
wherein electrically connecting the second stage pin electrical connection member to the first stage pin electrical connection member comprises receiving the one or more first electrical contacts of the first stage pin electrical connection member at the prong receiving gap when the first release lever separating base portion and the second release lever separating base portion are positioned between the electrically connected first and second stage pin electrical connection members.

20. The method of claim 19, wherein applying the removal force at the handle of the release lever causes each of the first release lever separating base portion and the second release lever separating base portion to move the second stage pin electrical connection member away from the first stage pin electrical connection member to disconnect the electrical connection between the first and second stage pin electrical connection members.
